(19) United States
(12) Patent Application Publication
(10) Pub. No.: US 2015/0382459 A1
(43) Pub. Date: Dec. 31, 2015

(54) Printed Circuit Board And Method For Fabricating The Same, And Apparatus For Fabricating Printed Circuit Borad

(71) Applicants: Shih-Chuan Tsai, Taipei (TW); Ching-Chang Yang, Hsinchu City (TW)

(72) Inventors: Shih-Chuan Tsai, Taipei (TW); Ching-Chang Yang, Hsinchu City (TW)

(21) Appl. No.: 14/751,400

(22) Filed: Jun. 26, 2015

(30) Foreign Application Priority Data
Jun. 30, 2014 (TW) 103122505

(51) Int. Cl. H05K 1/02; H05K 3/46; H05K 3/10; H05K 3/14; H05K 1/11; H05K 3/00

(52) U.S. Cl. CPC H05K 1/0298; H05K 1/115; H05K 3/0032; H05K 3/107; H05K 3/14; H05K 3/4644; H05K 2201/0137; H05K 2201/0332; H05K 2203/0736; H05K 2203/0759; H05K 2203/122; H05K 2203/0126; H05K 2201/09036

(57) ABSTRACT

The present disclosure provides a printed circuit board and a method for fabricating the same, and an apparatus for fabricating printed circuit board. The printed circuit board includes a substrate having an upper surface; a first trench in the upper surface of the substrate; a first via formed in the first trench and penetrating through the substrate; and a first conductive layer disposed in the first trench and the first via, the first trench is electrically connect to the first via. A method for fabricating the printed circuit board and an apparatus for fabricating the printed circuit board is also provided.

### RELATED APPLICATIONS

This application claims priority to Taiwanese Application Serial Number 103122505, filed Jun. 30, 2014, which is herein incorporated by reference.

### BACKGROUND

1. Field of Invention

The present invention relates to a printed circuit board and fabricating method of the same, and the apparatus for fabricating the printed circuit boards. More particularly, the present invention relates to a printed circuit board made by an inkjet manner, the corresponding fabricating method and apparatus for fabricating the printed circuit board.

2. Description of Related Art

Printed circuit boards are essential to the electronic products, which can allow the electronic components to be connected via the circuit on a printed circuit board and to play the whole function. The traditional method for fabricating the printed circuit board includes: forming an insulating layer on a substrate of a printed electroplating board; forming a metal layer on the insulating layer, such as a copper foil or aluminum foil; then processing partially masked, and etching the unmasked parts to form the conducting wires according to the circuit design; then processing lamination when the printed circuit board is a multilayered circuit board; after lamination, drilling and electroplating the multilayered circuit board, to allow different layers be conductive to each other.

As the rightsizing of the control systems, the current required on the printed circuit board also decreases, nowadays applications of printed circuit boards also apply to low-voltage applications and low current applications, thereby making the circuits on the circuit board to be reformed, resulting in the cut in thickness and width of circuits. The traditional screen printing and offset printing fail to satisfy the lately development and application requirements of the printed circuit board due to the precision problem. In addition, the traditional method for fabricating the printed circuit boards also has serious pollution problems, while the waste liquid treatment also increases costs.

### SUMMARY

Therefore the present invention using the inkjet printing technology in a printed circuit board fabricating method, which can significantly simplify the manufacturing process, save lots of complicated processes compared with the traditional manufacturing process, improve effectiveness of the process and the cost, and can reduce the pollution problems due to the production process. For example, this manufacturing process does not require the copper electroplating of the traditional process and the manner of etching copper foil for producing the circuit, thereby reducing the pollution created due to the etching process. In addition, the formed printed circuit board also has a fine circuit distribution and high precision. In the present invention, by using energy beam to combine the trench etch and the via etch, the circuit can be formed inside the trench, thereby making the printed circuit board fabricated by the present invention with a flat surface to reduce thickness of the printed circuit board, wherein the flat surface is conducive to manufacturing multilayered printed circuit board to various processing applications in the electronic industry.

One aspect of the present invention is to provide a printed circuit board, the printed circuit board includes a substrate having an upper surface; a first recess depressed in the upper surface of the substrate; a first via disposed in the first trench and penetrating through the substrate; and a first conductive layer disposed in the first trench and the first via, wherein the first via is electrically connected with the first trench.

According to some embodiments of the present invention, the said printed circuit board further includes a first insulating layer, which covers the first conductive layer within the first trench, and the first insulating layer does not cover an interior of the first via.

According to some embodiments of the present invention, a height of the first insulating layer is the same as the upper surface of the substrate.

According to some embodiments of the present invention, the aforementioned printed circuit board further includes: a second insulating layer, covering both the upper surface of the substrate and the first insulating layer; a second trench, formed at an upper surface of the second insulating layer; a second via, disposed in the second trench, and penetrating through the second insulating layer; a second conductive layer, formed in the second trench and inside the second via; and a third insulating layer, covering the second conductive layer and filling the second trench, and the third insulating layer does not cover an interior of the second via.

According to some embodiments of the present invention, a material of the conductive layer is a conductive paste or a conductive powder.

According to some embodiments of the present invention, materials of all of the first insulating layer, the second insulating layer, and the third insulating layer are resins.

One aspect of the present invention is to provide a fabricating method of a printed circuit board. The method includes: providing a substrate; using an energy beam to form a first trench and a first via in the first trench on an upper surface of the substrate; and spraying a conductive agent in the first trench and in the first via, to form a first conductive layer.

According to some embodiments of the present invention, the aforementioned method further includes: spraying an insulating agent to cover the first conductive layer within the first trench, to form a first insulating layer.

According to some embodiments of the present invention, a height of the first insulating layer is the same as the upper surface of the substrate.

According to some embodiments of the present invention, the aforementioned method further includes: forming a second insulating layer covered the upper surface of the substrate; using the energy beam to form a second trench and a second via within the second trench inside the second insulating layer; and spraying the conductive agent in the second trench and inside the second via, to form a second conductive layer.

According to some embodiments of the present invention, the aforementioned method further includes spraying the insulating agent to cover the second conductive layer, for forming a third insulating layer.

According to some embodiments of the present invention, a height of the third insulating layer is the same as an upper surface of the second insulating layer.

According to some embodiments of the present invention, material of all of the first insulating layer, the second insulating layer, and the third insulating layer are resins.

One aspect of the present invention is to provide an apparatus for fabricating a printed circuit board. The apparatus includes: a printed circuit board stage; a boring head of the printed circuit board, disposed on the printed circuit board stage; a conductive material nozzle, disposed on the printed circuit board stage; an insulating material nozzle, disposed on the printed circuit board stage; a three-dimensional moving apparatus, integrated at an appropriate location of the printed circuit board stage; and an operating system, connecting with the nozzles, the emitting head and the three-dimensional moving apparatus.

According to some embodiments of the present invention, the three-dimensional moving apparatus is used for moving the printed circuit board stage or moving the printed circuit board boring head, the conductive material nozzle and the insulating material nozzle.

According to some embodiments of the present invention, a conductive material used by the conductive material nozzle is a conductive paste or a conductive powder.

According to some embodiments of the present invention, a conductive material used by the conductive material nozzle is selected from a group consisting of gold, aluminum, copper, indium, antimony, magnesium, chromium, tin, nickel, silver, iron, titanium, alloys of the same and a combination thereof.

According to some embodiments of the present invention, an insulating material used by the insulating material nozzle is a resin or a dielectric material.

According to some embodiments of the present invention, the boring head of the printed circuit board is an energy beam emitting source.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1A˜FIG. 1F are diagrams illustrating top views and cross-sectional views of a fabricating method of a printed circuit board according to an exemplary embodiment of the present invention;

FIG. 2A˜FIG. 2F are diagrams illustrating top views and cross-sectional views of a fabricating method of a printed circuit board according to an exemplary embodiment of the present invention; and

FIG. 3 is a diagram illustrating an apparatus for fabricating a printed circuit board according to an exemplary embodiment of the present invention.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts. Certain terms are used throughout the following description and claims, which refer to particular components. As one skilled in the art will appreciate, electronic equipment manufacturers may refer to a component by different names. This document does not intend to distinguish between components that differ in name but not in function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

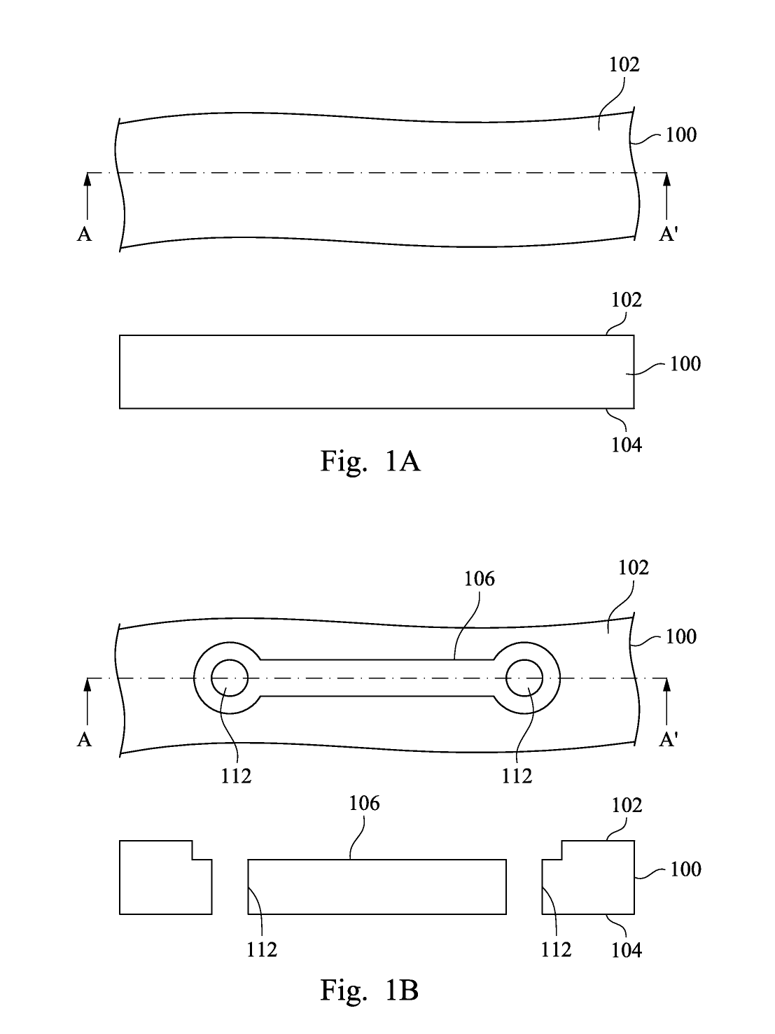

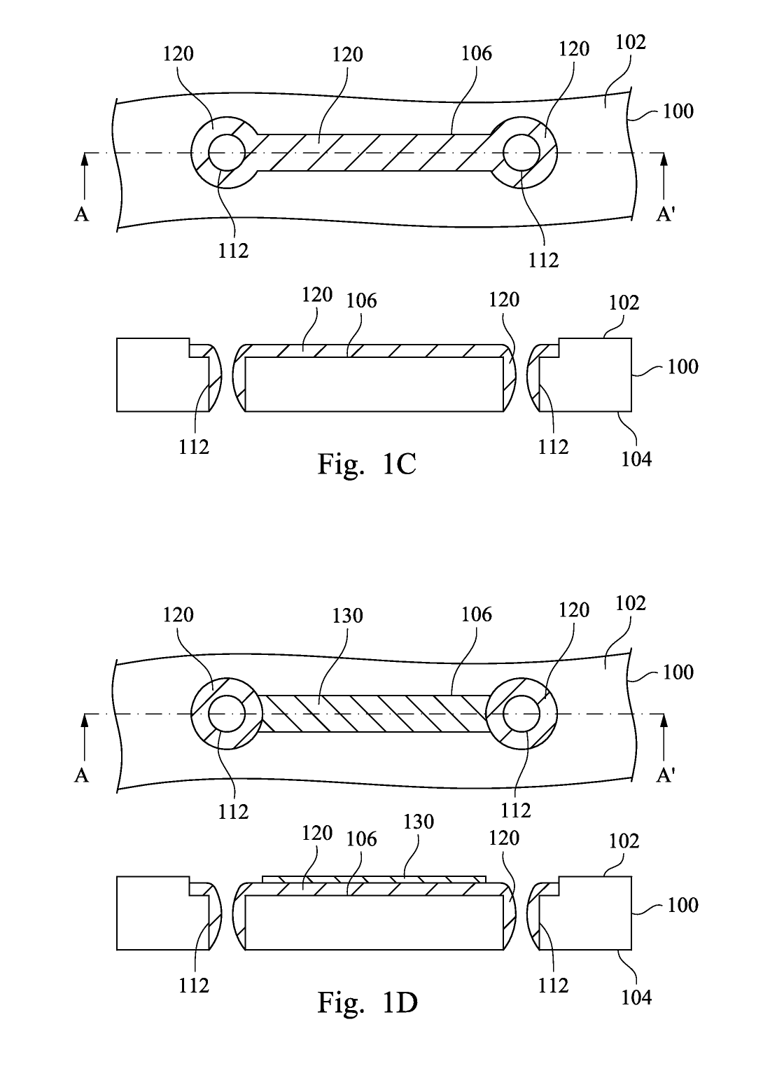

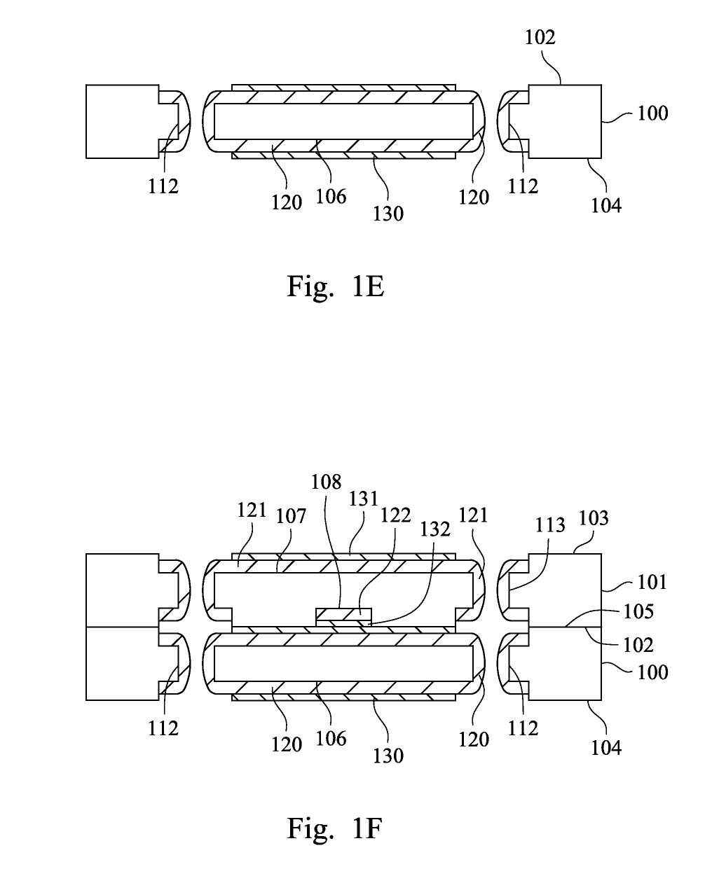

Please refer to FIG. 1A˜FIG. 1F. FIG. 1A˜FIG. 1F are diagrams illustrating top views and cross-sectional views of a fabricating method of a printed circuit board according to an exemplary embodiment of the present invention. Please refer to FIG. 1A. FIG. 1A is a diagram illustrating a top view of a substrate 100 of a printed circuit board and illustrating cross-sectional view taken along the plane designated by line AA′. By referring to both the top view and the cross-sectional view herein, a clear understanding of embodiments of the present invention can be obtained. The substrate 100 has an upper surface 102, and a lower surface 104. The substrate 100 can be a flexible substrate or a hard substrate, the material of the substrate 100 includes tissue, phenolic paper, epoxy resin, glass cloth, matte glass, polyester film, a polyimide film, silicon carbide, aluminum nitride and other materials, or combinations thereof, which are commonly used in the substrate of the printed circuit board.

Please refer to FIG. 1B. FIG. 1B is a diagram illustrating a top view and a cross-sectional views of a fabricating method of a printed circuit board according to an exemplary embodiment of the present invention. A first trench 106 is formed in the upper surface 102 of the substrate 100. The first trench 106 is created by using the energy beam to etch the upper surface 102 of the substrate 100. In some exemplary embodiments, the energy beam is a laser. The parts of the substrate 100 which are etched by the energy beam will be high-temperature gasification, and therefore no waste is generated and no pollution is caused during the manufacturing process. The energy beam also has the advantage of precise control, and therefore it can form the first trench 106 with a specific width and thickness. The first trench 106 is disposed at the position where the circuit of the printed circuit board is placed, and the shape of the first trench 106 can vary according to different circuit designs. A first via 112 is formed inside the first trench 106. The first via 112 can be formed by strengthening the energy of the energy beam in the first trench 106 to penetrate through the substrate 100. The first via 112 can be placed at the terminal points of the first trench 106 or at any suitable positions according to the circuit designs, and the first via 112 goes through the upper surface 102 and the lower surface 104 of the substrate 100. Circular recesses can be etched around the first via 112 to facilitate the follow-up process.

Please refer to FIG. 1C. FIG. 1C is a diagram illustrating a top view and a cross-sectional view of a fabricating method of a printed circuit board according to an exemplary embodiment of the present invention. As shown in FIG. 1C, the first conductive layer 120 is formed in the first trench 106 and inside the first via 112. The first conductive layer 120 is the circuit of the printed circuit board. The first conductive layer 120 can be formed in the first trench 106 and in the first via 112 by spraying a conductive agent by inkjet printing. And the first conductive layer 120 allows the first trench 106 to electrical connect to the first via 112. The materials of the conductive agent and the first conductive layer 120 can be conductive pastes or conductive powder. The conductive material in the conductive paste or the conductive powder is not limited, as long as it has conductivity. The material is a metal or a non-metal and the oxides, carbides, borides, nitrides or carbonitrides and combinations of above. The metal conductive particles can be, for example, gold, aluminum, copper, indium, antimony, magnesium, chromium, tin, nickel, silver, iron, titanium and its alloys and the corresponding oxides, carbides, borides, nitrides and carbonitrides particles. The non-metal particles can also be used, such as carbon particulates, including natural graphite sheets, expanded graphite, graphene, carbon black, nano-carbon and carbon nanotubes. In some exemplary embodiments, the first conductive layer 120 is lower than the upper surface 102 of the substrate 100. In some exemplary embodiments, the first conductive layer 120 does not fill the first via 112. The first conductive layer 120 in the first via 112 can ensure the electrical connection can be formed when the electronic components are plugged in the first via 112 of the printed circuit board, and no follow-up step for strengthening the electrical connections such as electroplating is required due to the unsuitable sizes of the via.

Please refer to FIG. 1D. FIG. 1D is a diagram illustrating a top view and a cross-sectional view of a fabricating method of a printed circuit board according to an exemplary embodiment of the present invention. As shown in FIG. 1D, a first insulating layer 130 is formed on the first conductive layer 120 in the first trench 106, and fills the first trench 106. A height of the first insulating layer 130 is the same as an upper surface 102 of the substrate to form a smooth surface of the printed circuit board. The design can avoid the circuit and the insulating layer from sticking out from the surface of the printed circuit board, thereby reducing the thickness of the printed circuit board, making the printed circuit board of a flat surface ease to stack to form a multilayered printed circuit board, and facilitating the subsequent package electronic component package. The first insulating layer 130 is used for protecting the first conductive layer 120, to keep the circuit of the printed circuit board isolated from outside thereby avoiding short circuit. The first insulating layer 130 is formed in the first trench 106 and covers the top of the first conductive layer 120 by spraying an insulating agent by the inkjet printing. The material of the insulating agent includes insulating materials which are commonly used in the printed circuit board, such as the resins or dielectric materials. The first insulating layer 130 is not formed on top of the first conductive layer 120 in the first via 112 to avoid obstructing the electrical connection efficiency of the electronic components. In some exemplary embodiments, the trench around the first via 112 is also not sprayed with the insulating agent to make the trench be easily handled in the subsequent processes such as soldering or putting solder paste, or proceeding electronic component assembly, and reducing the risk of the insulating agent falling into the via. The fabricating method of the printed circuit board using the energy beam etching and the inkjet printing to produce the printed circuit board, to provide good control and process convenience and eliminate the need for complex photoresist etching process, and significantly reduce cost and pollution, and can execute circuit design with higher precision. And the printed circuit board itself has the characteristics that the circuit is buried in the substrate. By etching the first trench 106 in the substrate 100, the first conductive layer 120 can be formed in the first trench 106 and is covered by the first insulating layer 130, and the printed circuit board can have a smooth surface which is suitable for the follow-up processes. For example, the touch screen of the plate and the mobile phone can hence reduce the border for hiding the display screen which is occupied by the wiring. And there is also a first conductive layer 120 in the first via 112 to promote the efficiency of the electrical connections and hence skip the following-up step for enhancing the conductivity.

Please refer to FIG. 1E. FIG. 1E is a diagram illustrating a top view and a cross-sectional view of a fabricating method of a printed circuit board according to an exemplary embodiment of the present invention. As shown in the figures, the printed circuit board in FIG. 1D can turn to the opposite side to execute the steps in FIG. 1B˜FIG. 1D again, including the energy beam etching, conductive layer and insulating layer printing to form a double-sided printed circuit board. The printed circuit board illustrated in FIG. 1E is a double-sided printed circuit board, and both the upper surface 102 and the lower surface 104 of the substrate 100 have the printed circuit. And the circuits are constructed by the first conductive layer 120, and are placed in the first trench 106 and are covered by the first insulating layer 130. The first via 112 electrically connects to the first conductive layer 120 of the upper surface 102 and the lower surface 104. The circuits of the double-sided printed circuit board can be designed according to various requirements.

Please refer to FIG. 1F. FIG. 1F is a diagram illustrating a cross-sectional view of a fabricating method of a printed circuit board according to an exemplary embodiment of the present invention. This diagram illustrates a structure of a multilayered printed circuit board. The multilayered printed circuit board can be laminated by the manner of the single-sided single-layered printed circuit board illustrated in FIG. 1D or by the manner of the double-sided single-layered printed circuit board illustrated in FIG. 1 F. The circuits of the printed circuit board can be designed according to different requirements, but the circuits are still buried in the printed circuit board. Hence the surfaces of the printed circuit board are all smooth surfaces and there is no wire on the surfaces. It is beneficial to form double-sided printed circuit board. In the exemplary embodiments in the above diagrams, two single-layer double-sided printed circuit board are laminated to form a double-layer printed circuit board.

A printed circuit board and a printed circuit board of the exemplary embodiment illustrated in FIG. 1E are stacked. The lower surface 105 of the substrate 101 connects to the upper surface 102 of the substrate 100. The upper surface 103 of the substrate 101 has a circuit distribution different from that of the lower surface 105. The upper surface 103 of the substrate 101 is etched by the energy beam to form the first trench 107 by the energy beam, the first conductive layer 121 is formed in the first trench 107 and is covered by the first insulating layer 131. The lower surface 105 of the substrate 101 is etched by the energy beam to form the first trench 108. A first conductive layer 122 is formed in the first trench 108 and is covered by the first insulating layer 132. In addition, the upper and the lower surface 103, 105 of the printed circuit board are smooth. The first via 113 penetrates through the substrate 101 and is covered by the first conductive layer 121, the first via 113 can electrically connect to the electronic components fabricated in the follow-up steps. In some exemplary embodiments, the laminated multilayered printed circuit board can be further etched by the energy beam to form the through hole penetrating through the multilayered printed circuit board, or the through hole can be made by connecting the first via 112 and 113 of each layer of the printed circuit board. In some exemplary embodiments, there is an adhesive layer between two layers of the printed circuit board.

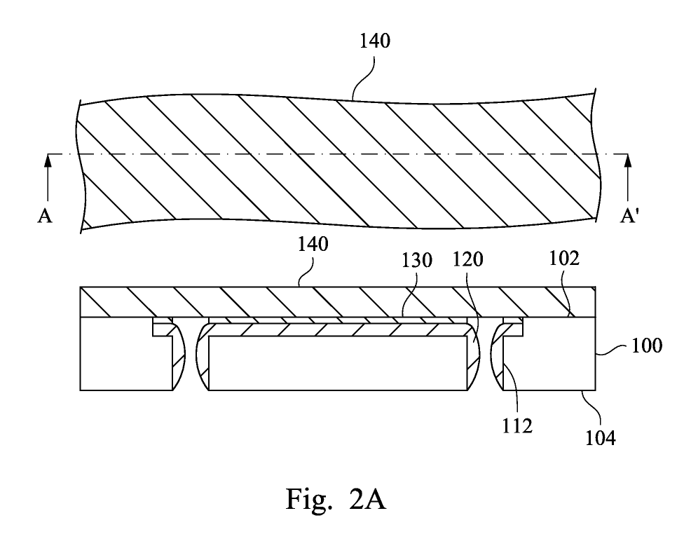

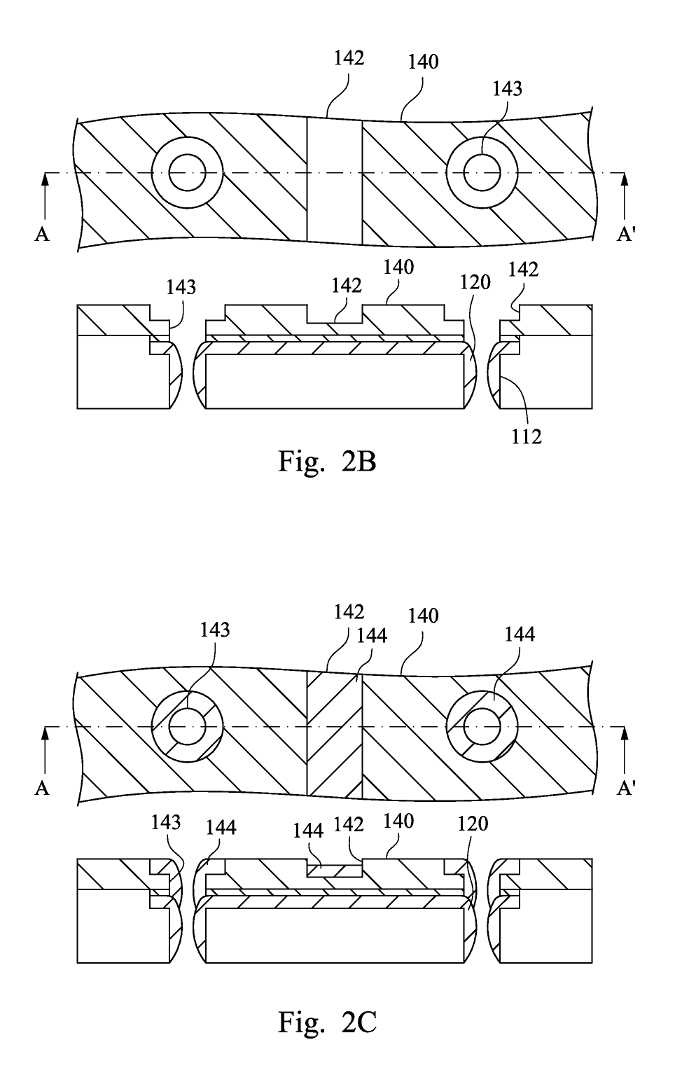

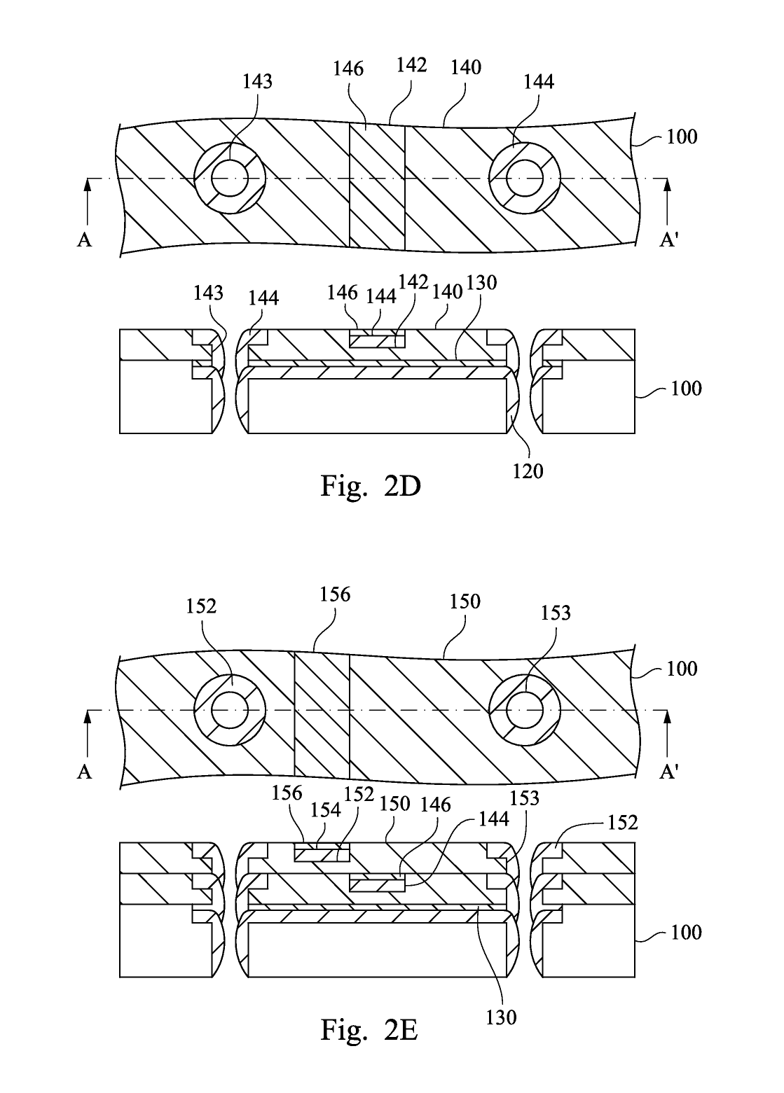

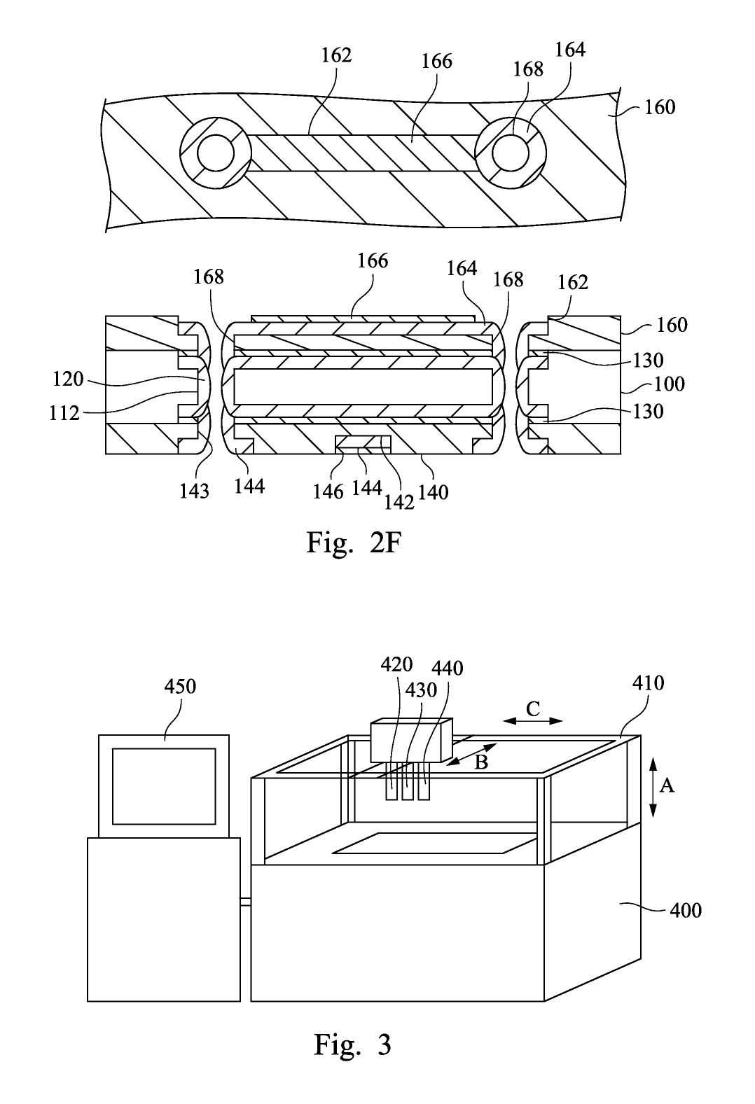

Please refer to FIG. 2A˜FIG. 2F. FIG. 2A˜FIG. 2F are diagrams illustrating top views and cross-sectional views of a fabricating method of a printed circuit board according to an exemplary embodiment of the present invention. FIG. 2A˜FIG. 2E are exemplary embodiments of forming a printed circuit on the structure of a single-layer printed circuit board, like the step illustrated in FIG. 1D. These embodiments can also form printed circuit boards with smooth surfaces. FIG. 2F is another exemplary structure of the same embodiment. Please refer to FIG. 2A. A second insulating layer 140 is formed on the upper surface 102 of the substrate 100 and on the first insulating layer 130, and covers the whole substrate 100. The second insulating layer 140 is formed by spraying an insulating agent by the inkjet printing on the upper surface 102 of the substrate 100. In some exemplary embodiments, the material of the insulating agent is resin. The second insulating layer 140 is used as another layer of substrate to form another layer of the circuits in the second insulating layer 140, and because of the presence of the second insulating layer 140, the circuit inside the second insulating layer 140 would not cause short circuiting of the first conductive layer 120 in the substrate 100.

Please refer to FIG. 2B. A second trench 142 is formed in the second insulating layer 140. The second trench 142 is formed by etching by the energy beam to allow the circuit to form in the second trench 142. In some exemplary embodiments, in the second trench 142 a second via 143 can also be formed and penetrating through the second insulating layer 140. The second via 143 is also formed by etching by the energy beam. In some exemplary embodiments, the second via 143 can be opposite to the first via 112 and electrically connect to each other. The distribution of the second trench 142 and the second via 143 can be designed according to the circuit requirements.

Please refer to FIG. 2C. A second conductive layer 144 is formed in the second trench 142. The second conductive layer 144 is formed in the second trench 142 by spraying a conductive agent by the inkjet printing. In some exemplary embodiments, the second via 143 in the second trench 142 also has the second conductive layer 144, and thereby the second via 143 can electrically connect to some parts of the first conductive layer 120 of the substrate 100. In addition, the surface of the second conductive layer 144 does not stick out from the second trench 142.

Please refer to FIG. 2D. A third insulating layer 146 is formed on the second conductive layer 144 and fills the second trench 142. The third insulating layer 146 is used for protecting the second conductive layer 144 and making the surface of the second insulating layer 140 recover to be smooth. The third insulating layer 146 is formed in the second trench 142 by spraying an insulating agent by the inkjet printing, thereby the printed circuit board becoming a printed circuit board with double layers of circuits. In some exemplary embodiments, the third insulating layer 146 is not formed on the second conductive layer 144 around the second via 143, for avoiding poor conductivity of the second via 143.

Please refer to FIG. 2E. FIG. 2E is a diagram illustrating a printed circuit board having three layers of circuits of the present invention. By repeating the steps from FIG. 2A˜FIG. 2D, another layer of circuit can be formed on the existing printed circuit board. As shown in FIG. 2E, another second insulating layer 150 is formed on the second insulating layer 140. Another second trench 152 is formed in the second insulating layer 150, and another second via 153 is formed in the second trench 152. Another second conductive layer 154 is formed inside the second trench 152, and another third insulating layer 156 covers on the some parts of the second conductive layer 154. The second insulating layer 150, the second conductive layer 154 and the third insulating layer 156 are all formed by the inkjet printing, while the second trench 152 and the second via 153 are formed by etching by the energy beam. The materials of the conductive layer and the insulating layer are all the same as the materials in the aforementioned exemplary embodiment.

Please refer to FIG. 2F. FIG. 2F illustrates a two-sided multilayered circuit board which is made by turning over the printed circuit board illustrated in FIG. 2D to the opposite side and then repeating the steps in FIGS. 2A˜2D. Circuits are formed on both the upper surface and the lower surface of the substrate 100. And the circuit is constructed by the first conductive layer 120 and exists in the first trench, being covered by the first insulating layer 130. The second insulating layer 140 covers the lower surface of the substrate 100. The second trench 142 and the second via 143 are inside the second insulating layer 140. The second conductive layer 144 and the third insulating layer 146 are formed in the second trench 142 and do not stick out from the surface of the second insulating layer 140. In some exemplary embodiments, the third insulating layer 146 does not cover the second conductive layer 144 around the second via 143. A second insulating layer 160 covers the upper surface of the substrate 100. The second trench 162 and the second via 168 inside the second trench 162 are both formed by etching by the energy beam. The second conductive layer 164 is sprayed in the second trench 162 and the second via 168, and the second conductive layer 164 electrically connects to the first conductive layer 120. A third insulating layer 166 is sprayed in the second trench 162, but it is not sprayed in the second via 168 or the place around the second via 168. The structure can form into multilayers of circuits on the double-sided circuit board and still keep the circuit board with smooth surfaces. In addition, since the thickness of the second insulating layer is less than that of the substrate, it can also form the thinner printed circuit board having multilayer circuits. The positions and the number of the second via 168 can vary according to the circuit designs, or it can be placed in the middle of the second trench 162 or does not align with the first via 112. In addition, it is allowed to stack and press a plurality of the structure of the printed circuit board herein to form a printed circuit board with more layers.

The fabricating method of the printed circuit board which uses the energy beam etching and the inkjet printing manners can form a printed circuit board having multilayer circuits by using the steps illustrated from FIG. 2A˜FIG. 2F. In addition, in the exemplary embodiment disclosed in the FIG. 2D˜FIG. 2F, the printed circuit board can be stacked to form the printed circuit board with more layers. In addition, since all the printed circuit boards in the present invention have smooth surfaces, it facilitates the follow-up processes or makes multilayered printed circuit board. In addition, in the present invention the method for fabricating the printed circuit board does not need the traditional photo resistances and the chemical etching manufacturing processes. It largely reduces the pollution generated during the manufacturing processes, such as, avoiding the pollution made by the copper foil and the etching liquid during forming the circuit. Compared with the conventional process, the present invention can significantly reduce the manufacturing process, eliminate many complex processes, and promote the manufacturing process and is cost efficiency. And it further enhances the precision of the fabricated printed circuit board. And the circuits of the fabricated printed circuit board are buried in the trenches, and the present invention makes the trenches electrically connect to the through hole, while the manner which the inkjet printing completes forming the circuits in one go ensures the stability of the circuit connections, thereby satisfying the electrical connection requirements when the electronic components are assembled on the circuit board.

Please refer to FIG. 3. FIG. 3 is a diagram illustrating an apparatus for fabricating a printed circuit board according to an exemplary embodiment of the present invention. The apparatus for fabricating a printed circuit board includes a printed circuit board stage 400, a three-dimensional moving apparatus 410, a boring head 420 of the printed circuit board, a conductive material nozzle 430, an insulating material nozzle 440 and an operating system 450. The printed circuit board stage 400 is used for carrying the substrate of the printed circuit board such that the printed circuit board can be fabricated and processed on the printed circuit board stage 400. The printed circuit board stage 400 can have a printed circuit board fixing and positioning apparatus for fixing the substrate of the printed circuit board. In some of the exemplary embodiments, the stage 400 has a vacuum device, which can create a vacuum between the substrate of the printed circuit board and the printed circuit board stage 400 to fix the printed circuit board. The boring head 420 of the printed circuit board, the conductive material nozzle 430 and the insulating material nozzle 440 are disposed on the printed circuit board stage 400 for processing the fabrication of the printed circuit board.

The boring head 420 of the printed circuit board can be an energy beam emitting head for etching trenches and vias of the printed circuit substrate and making the circuit form in the trench. In some exemplary embodiments, the energy beam emitting head is a laser emitting head. The conductive material nozzle 430 is used for inkjet printing the conductive agent to the trench or on the surface of the substrate to form the circuits. The conductive agent includes conductive powder and conductive pastes. The conductive powder and conductive pastes include conductive materials, such as a metal or a non-metal and the oxides, carbides, borides, nitrides or carbonitrides or the combinations thereof. The metal conductive particles can be, for example, gold, aluminum, copper, indium, antimony, magnesium, chromium, tin, nickel, silver, iron, titanium and its alloys and the corresponding oxides, carbides, borides, nitrides and the carbonitrides particles. The non-metal particles can be carbon particulates, including natural graphite sheets, expanded graphite, graphene, carbon black, nano-carbon and carbon nanotubes. The insulating material nozzle 440 is used for inkjet printing the insulating agent to form insulating layers to protect the circuit. The insulating material of the insulating agent is a resin or a dielectric material. It is allowed to use additional conductive material nozzle or insulating material nozzle of different materials to achieve the applications of automatically operating/fabricating the printed circuit boards. The nozzles and the boring head may be disposed on the top of the printed circuit board stage by the mechanical arms or the three-dimensional moving apparatus to facilitate the fabrication of the printed circuit board.

The three-dimensional moving apparatus 410 and the printed circuit board stage 400 are assembled in a way that allows to move up and down (A direction), left and right (B direction) and back and forth (C direction). The three-dimensional moving apparatus can be assembled with the printed circuit board stage directly for transporting the substrate of the printed circuit board and to move the printed circuit board stage and the substrate when the nozzles 430 and 440 and the boring head 450 are fixed so as to proceed the fabricating steps. Alternatively, the three-dimensional moving apparatus can be assembled with the nozzles 430 and 440 and the boring head 450 so as to integrate the nozzles 430 and 440 and the boring head 450 onto the three-dimensional moving apparatus. In this way, the three-dimensional moving apparatus can move the nozzles 430 and 440 and the boring head 450 to proceed the steps for fabricating the printed circuit board while the substrate of the printed circuit board is fixed. The three-dimensional moving apparatus can include devices such as a slide, a stepping motor, or a timing bell/pulley for moving three-dimensionally, and the aforementioned three-dimensional moving apparatus and the moving means are some exemplary embodiments and are not meant to be limitations of the present invention. That is, all the apparatus and devices which can execute the three-dimensional operations to control the printing positions can be applied in the present invention. The operating system 450 connects to the three-dimensional moving apparatus 410, the printed circuit board boring head 420, the conductive material nozzle 430 and the insulating material nozzle 440 for controlling these devices. In some exemplary embodiments, the operating system 450 includes a computer. The computer can control the three-dimensional moving apparatus 410 to specific positions and operate the printed circuit board boring head 420, the conductive material nozzle 430 or the insulating material nozzle 440 according to the requirements, such as, controlling the depth of the drill holes, or the spraying dosages of the conductive agent or the insulating agent of the nozzles so as to form the printed circuit board disclosed in the aforementioned exemplary embodiments. Through integrating the etching technology and the inkjet printing technology into the printed circuit board fabricating apparatus, the present invention allows a fabricating method of the printed circuit board of the present invention by using a single apparatus. In this way, the present invention provides more convenient and faster manufacturing process, in addition, the printed circuit board can be used in mass production. Compared with the conventional process, the apparatus and the fabricating method of the present invention can greatly reduce the printed circuit board manufacturing process, eliminate many complex processes, and improve process and is cost efficiency.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A printed circuit board, comprising:
a substrate having an upper surface;
a first trench depressed in the upper surface of the substrate;
a first via disposed in the first trench, and penetrating through the substrate; and
a first conductive layer disposed in the first trench and the first via, wherein the first via is electrically connected to the first trench.

2. The printed circuit board of claim 1, further comprising a first insulating layer, covering the first conductive layer in the first trench, and an interior of the first via is not covered by the first insulating layer.

3. The printed circuit board of claim 2, wherein a height of the first insulating layer is the same as the upper surface of the substrate.

4. The printed circuit board of claim 2, further comprising:
a second insulating layer covering the upper surface of the substrate and the first insulating layer;
a second trench formed on an upper surface of the second insulating layer;
a second via disposed in the second trench and going through the second insulating layer;
a second conductive layer formed in the second trench and inside the second via; and
a third insulating layer covering the second conductive layer and filling the second trench, wherein an interior of the second via is not covered by the third insulation layer.

5. The printed circuit board of claim 1, wherein a material of the conductive layer is a conductive paste or a conductive powder.

6. The printed circuit board of claim 4, wherein materials of the first insulating layer, the second insulating layer, and the third insulating layer are resins.

7. A method for fabricating a printed circuit board, comprising:
providing a substrate;
using an energy beam to form a first trench and a first via in the first trench on an upper surface of the substrate; and
spraying a conductive agent in the first trench and in the first via to form a first conductive layer.

8. The method of claim 7, further comprising:
spraying an insulating agent to cover the first conductive layer in the first trench to form a first insulating layer.

9. The method of claim 8, wherein a height of the first insulating layer is the same as the upper surface of the substrate.

10. The method of claim 8, further comprising:
forming a second insulating layer covering the upper surface of the substrate;
forming a second trench and a second via in the second trench in the second insulating layer by using energy beam; and
spraying the conductive agent in the second trench and inside the second via, to form a second conductive layer.

11. The method of claim 10, further comprising:
spraying the insulating agent to cover the second conductive layer for forming a third insulating layer.

12. The method of claim 11, wherein a height of the third insulating layer is the same as an upper surface of the second insulating layer.

13. The method of claim 11, wherein materials of the first insulating layer, the second insulating layer, and the third insulating layer are resins.

14. An apparatus for fabricating a printed circuit board, comprising:
a printed circuit board stage;
a boring head of the printed circuit board disposed on the printed circuit board stage;
a conductive material nozzle disposed on the printed circuit board stage;
an insulating material nozzle disposed on the printed circuit board stage;
a three-dimensional moving apparatus integrated at an appropriate location on the printed circuit board stage; and
an operating system connecting to the nozzles the boring head and the three-dimensional moving apparatus.

15. The apparatus of claim 14, wherein the three-dimensional moving apparatus is used for moving the printed circuit board stage or moving the boring head of the printed circuit board, the conductive material nozzle and the insulating material nozzle.

16. The apparatus of claim 14, wherein a conductive material used by the conductive material nozzle is a conductive paste or a conductive powder.

17. The apparatus of claim 14, wherein a conductive material used by the conductive material nozzle is selected from a group consisting of gold, aluminum, copper, indium, antimony, magnesium, chromium, tin, nickel, silver, iron, titanium, alloys of the same and a combination thereof.

18. The apparatus of claim 14, wherein an insulating material used by the insulating material nozzle is resin or a dielectric material.

19. The apparatus of claim 14, wherein the boring head of the printed circuit board is an energy beam emitting source.
